(19) United States
(12) Patent Application Publication
(10) Pub. No.: US 2024/0327119 A1
(43) Pub. Date: Oct. 3, 2024

(54) SHUTTLE STORAGE AND METHOD FOR PRODUCING THE SAME

(71) Applicant: Fabmatics GmbH, Dresden (DE)

(72) Inventors: Karsten BUDACH, Dresden (DE); Martin ENGEL, Dresden (DE); Alexander GUERBIG, Dresden (DE)

(21) Appl. No.: 18/585,591

(22) Filed: Feb. 23, 2024

(30) Foreign Application Priority Data
Feb. 23, 2023 (EP) EP23158267.7

(51) Int. Cl. B65G 1/04

(52) U.S. Cl. CPC B65G 1/0492; B65G 1/0464; B65G 2201/0297

(57) ABSTRACT

A shuttle storage for transport boxes for wafer discs, the shuttle storage including a horizontal drive alley for a storage vehicle; a linear motor for the storage vehicle, the linear motor arranged on a floor of the drive alley; a transfer station configured to transfer the transport boxes into or from the shuttle storage; a support structure that is suspended from a room ceiling; storage spaces for the transfer boxes, wherein the storage spaces are attached at the support structure in a horizontally extending storage plane along the drive alley; ceiling elements attached at the room ceiling; and support elements for the storage spaces, wherein the support elements are attached at the ceiling elements so that the support elements are adjustable with respect to vertical height.

### RELATED APPLICATIONS

This application claims priority from and incorporates by reference European patent application EP 23 158 267.7 filed on Feb. 23, 2023.

### FIELD OF THE INVENTION

The invention relates to a shuttle storage for transport boxes for wafer discs. The invention furthermore relates to a method for producing the shuttle storage.

### BACKGROUND OF THE INVENTION

A generic shuttle storage like disclosed e.g. in WO 03/046954 A2 and DE 20 2012 000 143 U1 is used in particular for storing wafer discs in a semi-conductor production clean room.

In order to prevent damaging the sensitive wafer discs during storage and handling, storage spaces and transport paths have to be aligned with each other precisely. The configuration of the known shuttle storage which is based on a room ceiling that is fabricated with significantly higher tolerances is very demanding with respect to materials, procedures and operator skills.

DE 10 2008 015 472 A1 discloses storage spaces for a shuttle storage wherein the storage spaces can be leveled individually along an overhead trolley. KR 2021 014 3566 A discloses a shuttle storage with a rail supported storage vehicle.

### BRIEF SUMMARY OF THE INVENTION

Thus, it is an object of the invention to simplify the fabrication of a shuttle storage.

Improving upon the known shuttle storage the object is achieved by a shuttle storage for transport boxes for wafer discs, the shuttle storage including a horizontal drive alley for a storage vehicle; a linear motor for the storage vehicle, the linear motor arranged on a floor of the drive alley; a transfer station configured to transfer the transport boxes into or from the shuttle storage; a support structure that is suspended from a room ceiling; storage spaces for the transfer boxes, wherein the storage spaces are attached at the support structure in a horizontally extending storage plane along the drive alley; ceiling elements attached at the room ceiling; and support elements for the storage spaces, wherein the support elements are attached at the ceiling elements so that the support elements are adjustable with respect to vertical height.

The object is also achieved by a method for producing a shuttle storage for transport boxes for wafer discs, the shuttle storage including a horizontal drive alley for a storage vehicle; a linear motor for the storage vehicle, the linear motor arranged on a floor of the drive alley; a transfer station configured to transfer the transport boxes into or from the shuttle storage; a support structure that is suspended from a room ceiling; storage spaces for the transfer boxes, wherein the storage spaces are attached at the support structure in a horizontally extending storage plane along the drive alley, the method comprising: initially attaching ceiling elements at the room ceiling; thereafter attaching support elements at the ceiling elements; thereafter leveling the support elements for the storage spaces with respect to vertical height in the storage plane; and thereafter attaching the storage spaces at the support elements.

Storage material is moved in a shuttle storage horizontally in the drive alley by an autonomous storage vehicle designated as shuttle and moved perpendicular to the storage plane by a separate lifting station or elevator outside of the drive alley. The transport boxes in the shuttle storage according to the invention, are typically standard containers designated as Carriers, HA200, SMIF or FOUP.

The attachment of the support structure at the room ceiling is decoupled from the orientation and mounting of the storage spaces and the transport paths by the adjustable support elements. The shuttle storage according to the invention facilitates and accelerates procurement, storage, planning and assembly.

Advantageously the support elements in a shuttle storage according to the invention are offset from one another in the longitudinal direction of the drive alley by a grid spacing. The grid facilitates standardization of planning and production of the shuttle storage.

Advantageously the storage spaces in the shuttle storage according to the invention are preassembled in storage groups which have a single grid spacing or a multiple of the single grid spacing advantageously two or three times the grid spacing in a longitudinal direction of the drive alley. Further advantageously floor groups that complete the shuttle storage at the bottom have a corresponding dimension.

Pre-assembled modules accelerate mounting the shuttle storage according to the invention and thus reduce in particular shut down times of existing fabrication arrangements below the storage level. Additionally storage management is simplified by a reduced number of different components for producing the shuttle storage.

Further advantageously the shuttle storage according to the invention includes start and end modules that limit the drive alley on one side and a transfer module with a transfer station. This modular structure simplifies planning the shuttle storage according to the invention.

Using modules and sub-assemblies with a uniform grid spacing increases flexibility and adaptability of the shuttle storage according to the invention with respect to different space requirements and reduces the number of different components and thus storage complexity.

Advantageously the ceiling elements of the shuttle storage according to the invention include two respective support elements that are arranged at the drive alley opposite to one another and advantageously include a horizontally extending stabilization element between the support elements 13. The attachment between support elements 13 arranged opposite to one another prevents a pivoting of storage spaces and transport path transversal to the drive alley. The stabilization element simplifies assembly of the support elements arranged opposite to one another at the room ceiling at a predetermined distance.

Advantageously the shuttle storage according to the invention includes a linear motor for the storage vehicle. Further advantageously the linear motor is arranged in the floor of the drive alley. The storage vehicle is advantageously provided with energy through in induction. Compared to alternative drives by belt axles or gear racks and alterative energy supplies by cables and cable chains or slip contacts the shuttle storage according to the invention prevents abrasion and particle admission upon the wafers in particular under clean room conditions.

Advantageously a shuttle storage according to the invention incudes a floor of the drive alley that has a grid shaped configuration. Further advantageously the shuttle storage according to the invention includes external walls arranged parallel to the drive alley. Both prevents external interference with the storage spaces and transport paths of the shuttle storage while still facilitating a laminar vertical flow through of storage spaces and transport path top down in order to prevent a contamination of the wafer discs.

Advantageously the storage spaces in the shuttle storage according to the invention are arranged in two rows on both sides of the drive alley. This doubles the capacity of the shuttle storage according to the invention.

A shuttle storage according to the invention can have plural transfer stations. Plural shuttle storages according to the invention above or adjacent to one another can be combined into a storage device.

Improving upon the known method, it is proposed according to the invention that a support structure is attached at the room ceiling and preassembled modules are engaged in the support structure in a horizontally extending storage plane, wherein the preassembled modules form the shuttle storage. The method according to the invention facilitates producing a shuttle storage according to the invention and is characterized by its advantages recited supra.

Advantageously support elements of the support structure are vertically levelled into the storage plane after attaching the support structure at the room ceiling according to the method according to the invention. After attaching the support structure at the room ceiling the support elements can be levelled in a particularly simple manner using a laser levelling device. When the modules are mounted thereafter, they do not interfere with the levelling.

The shuttle storage according to the invention facilitates a drive alley with a single vehicle and with a length of up to 48 meters.

### BRIEF DESCRIPTION OF THE DRAWINGS

The invention is subsequently described based on embodiments with reference to drawing figures, wherein:

FIG. 1 illustrates a shuttle storage according to the invention;

FIG. 2 illustrates a ceiling element of the shuttle storage;

FIG. 3 illustrates a profile cross section;

FIG. 4 illustrates a detail of the ceiling element;

FIG. 5 illustrate an end module of the shuttle storage;

FIG. 6 illustrates a triple module of the shuttle storage;

FIG. 7 illustrates a transfer module of the shuttle storage;

FIG. 8 illustrates a simple module of the shuttle storage; and

FIG. 9 illustrates a sectional view of the shuttle storage.

### DETAILED DESCRIPTION OF THE INVENTION

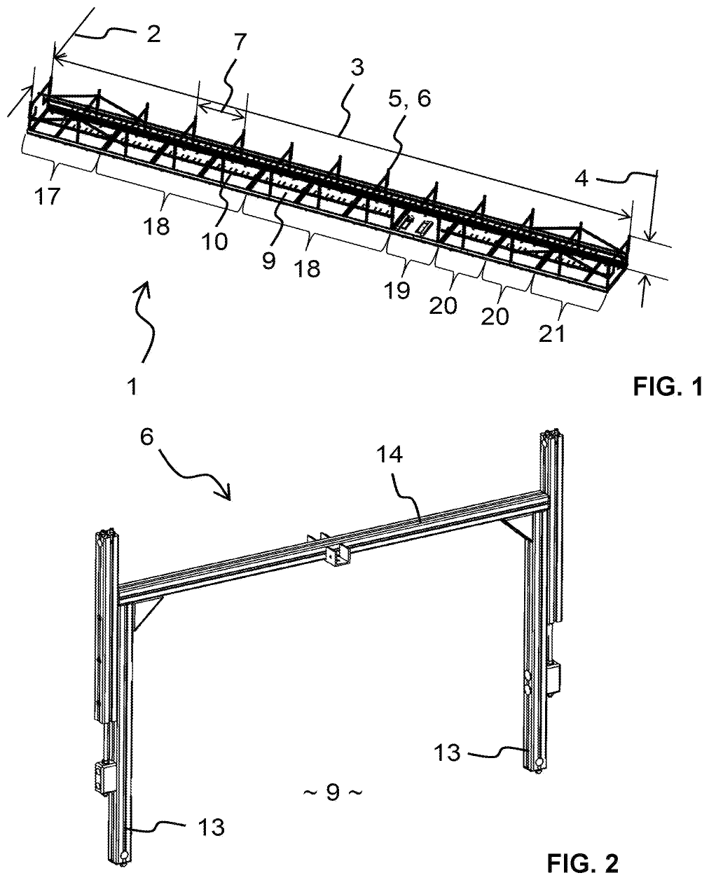

The shuttle storage 1 according to the invention illustrated in FIG. 1 has a width of 124 cm, a length 3 of 1446 cm and a height 4 of 90 cm and is arranged in a clean room for semi-conductor production under an uneven room ceiling A.

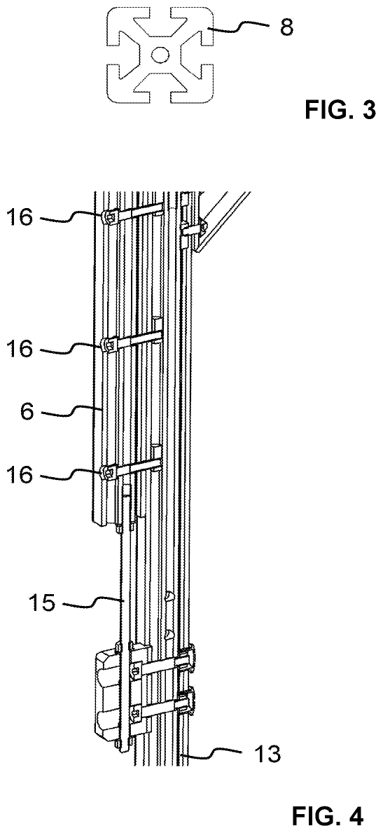

In order to produce the shuttle storage 1 a support structure 5 with ceiling elements 6 illustrated in FIG. 2 is attached at the room ceiling A offset by a grid spacing 7 of 120 cm. The ceiling elements 6 are essentially made from a T-groove profile with a square cross section 8 of 40 mm×40 mm shown in FIG. 3

The shuttle storage 1 includes two rows 10 arranged on both sides of a horizontally extending drive alley 9 including a total of 80 storage spaces 11 for transport boxes 12 illustrated in FIG. 8. The transport boxes 12 are standardized open containers for up to 25 wafer discs with a diameter of 200 mm.

Each of the ceiling elements 6 includes two support elements 13 respectively arranged on both sides of the drive alley 9, wherein the support elements are connected U-shaped by a stabilization element 14 transversal to the drive alley 9. After being attached at the room ceiling A, the support elements 13 are levelled by a threaded rod 15 at the ceiling elements 6 in an adjustment range of 10 cm vertically to a level of a storage plane B using a laser levelling system with a bubble and laser generated line in order to compensate for the uneven room ceiling A and thereafter the support elements 13 are fixed in the respectively selected position using three clamping bolts 16.

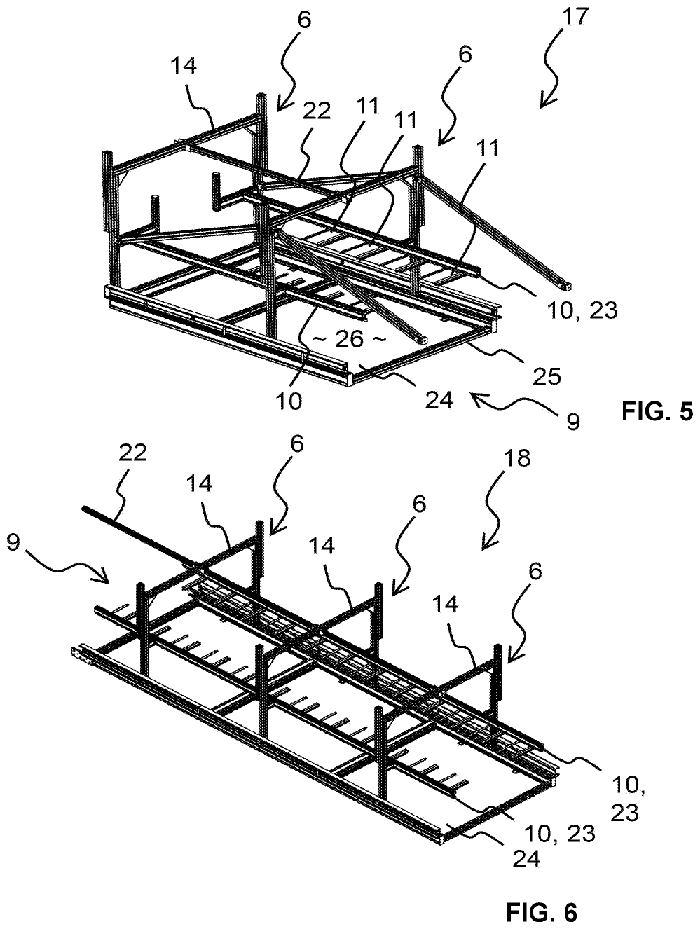

The shuttle storage 1 is planned with five standard modules, namely a start module 17, two triple modules 18, a transfer module 19, two single modules 20 and an end module. The start module 17, the triple module 18 and the transfer module 19 and the single module 20 are shown by themselves in FIGS. 5-8.

The planned modules respectively include the associated ceiling elements 6, receivers 22 for the power supplies between the ceiling elements 6 in the longitudinal direction of the drive alley 9, one or plural storage groups 23, a floor group 24 with a frame 25 made from the aluminium profile and a grid shaped floor element 26 inserted therein schematically illustrated in FIG. 8 and side walls 27. The end module 21 mirrors the start module 17, but includes two additional side walls 27 and an additional receiver 22 for the power supply along the drive alley 9.

The single module 20 and the transfer module 19 has a single grid spacing 7 along the drive alley 9, the triple module 18 has triple grid spacing 7, the start module 17 and the end module 21 has 1.5 times the grid spacing.

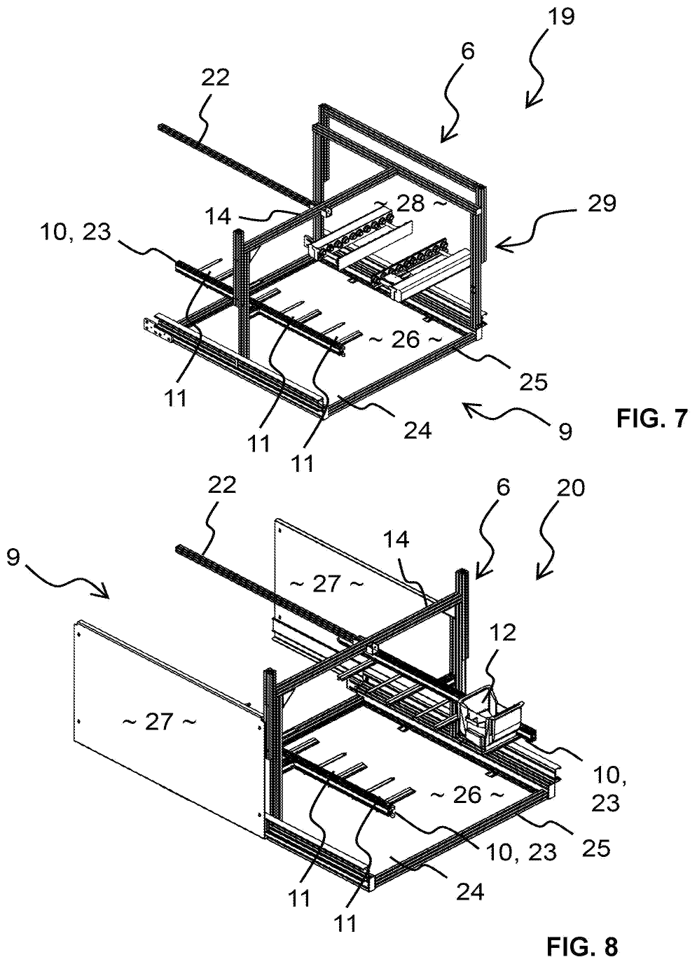

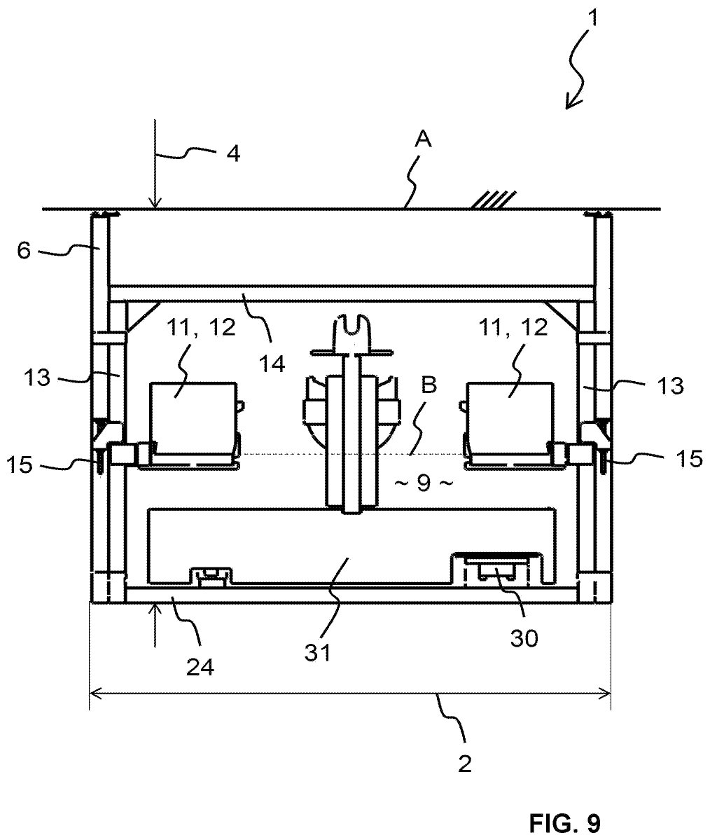

The transfer module 19 includes a storage group 23 and an opening 28 arranged opposite to the storage group and configured for the transfer station 29 shown in FIG. 7. All other modules include two storage groups 23 arranged opposite to one another along the drive alley 9. Each storage group 23 includes four storage spaces 11 per grid spacing 7.

In order to assemble the shuttle storage 1 after the levelling, the receivers 22 for the power supply are arranged along the drive alley 9, then the preassembled storage groups 23 and the base groups 24 and the side walls 27 are mounted at the support elements 13 and eventually a linear motor 30 for the storage vehicle 31 is mounted along the drive alley 9 on the floor groups 24, and a lifting station with the transfer station 29 is provided at the transfer module 19.

The storage vehicle 31 is provided with energy by induction through a current pickup from the receivers 22 for the power supply.

### REFERENCE NUMERALS AND DESIGNATIONS

1 shuttle storage
2 width
3 length
4 height
A room ceiling
5 support structure
6 ceiling element
7 grid spacing
8 cross section
9 drive alley
10 row
11 storage space
12 transport box
13 support element
14 stabilization element
15 threaded rod
16 clamping bolt
B storage plane
17 start module
18 triple module
19 transfer module
20 single module
21 end module
22 receiver for power supply
23 storage group
24 base group
25 frame
26 base element
27 side wall
28 opening
29 transfer station
30 linear motor
31 storage vehicle

What is claimed is:

1. A shuttle storage for transport boxes for wafer discs, the shuttle storage comprising:
a horizontal drive alley for a storage vehicle;
a linear motor for the storage vehicle, the linear motor arranged on a floor of the drive alley;
a transfer station configured to transfer the transport boxes into or from the shuttle storage;
a support structure that is suspended from a room ceiling;
storage spaces for the transfer boxes, wherein the storage spaces are attached at the support structure in a horizontally extending storage plane (B) along the drive alley;
ceiling elements attached at the room ceiling; and
support elements for the storage spaces, wherein the support elements are attached at the ceiling elements so that the support elements are adjustable with respect to vertical height.

2. The shuttle storage according to claim 1, wherein the support elements are offset from one another in a longitudinal direction of the drive alley by a grid spacing.

3. The shuttle storage according to claim 2, further comprising: preassembled storage groups including the storage spaces and/or floor groups that terminate the shuttle storage at a bottom, wherein the floor groups are offset from one another by the grid spacing in the longitudinal direction or by 2× or 3× the grid spacing.

4. The shuttle storage according to claim 2, further comprising: a start module and an end module including a one-sided boundary of the drive alley and at least one transfer module including the transfer station.

5. The shuttle storage according to claim 1, wherein the ceiling elements respectively include two support element arranged on opposite sides of the drive alley and a horizontal stabilization element arranged between the support elements.

6. The shuttle storage according to claim 1, further comprising: a grid shaped floor of the drive alley and outer walls arranged parallel to the drive alley.

7. The shuttle storage according to claim 1, wherein the storage spaces are arranged in two rows with one row of the two rows arranged on each side of the drive alley.

8. A method for producing a shuttle storage for transport boxes for wafer discs, the shuttle storage including
a horizontal drive alley for a storage vehicle;
a linear motor for the storage vehicle, the linear motor arranged on a floor of the drive alley;
a transfer station configured to transfer the transport boxes into or from the shuttle storage;
a support structure that is suspended from a room ceiling;
storage spaces for the transfer boxes, wherein the storage spaces are attached at the support structure in a horizontally extending storage plane along the drive alley, the method comprising:
initially attaching ceiling elements at the room ceiling; thereafter
attaching support elements at the ceiling elements; thereafter
leveling the support elements for the storage spaces with respect to vertical height in the storage plane; and thereafter
attaching the storage spaces at the support elements.
